(19) United States
(12) Patent Application Publication
(10) Pub. No.: US 2022/0033679 A1
(43) Pub. Date: Feb. 3, 2022

(54) BACKSHEET FOR PHOTOVOLTAIC MODULES COMPRISING AN ALIPHATIC POLYAMIDE

(71) Applicant: DSM ADVANCED SOLAR B.V., Geleen (NL)

(72) Inventors: Franciscus Gerardus Henricus VAN DUIJNHOVEN, Echt (NL); Robert JANSSEN, Echt (NL)

(21) Appl. No.: 17/279,902

(22) PCT Filed: Sep. 25, 2019
(86) PCT No.: PCT/EP2019/075905

§ 371 Date: Mar. 25, 2021

(30) Foreign Application Priority Data
Sep. 28, 2018 (EP) 18197665.5

(51) Int. Cl. C09D 177/06; C09J 7/24; C09J 151/06; C08L 77/06; C09D 153/00; C08J 5/18; C09D 123/14; H01L 31/048; B32B 27/08; B32B 27/34; B32B 27/32; B32B 27/30; B32B 7/12

(52) U.S. Cl. CPC C09D 177/06; B32B 2457/12; C09J 151/06; C08L 77/06; C09D 153/005; C08J 5/18; C09D 123/142; H01L 31/0481; B32B 27/08; B32B 27/34; B32B 27/32; B32B 27/306; B32B 27/308; B32B 7/12; C09J 2453/00; C08J 2323/14; C09J 2423/106; C09J 7/243

(57) ABSTRACT

The present invention relates to a backsheet for photovoltaic modules comprising a polymeric layer comprising an aliphatic polyamide comprising 1,10-decanedioic acid. Examples of such aliphatic polyamides are polyamide 4,10, polyamide 5,10 or polyamide 6,10. Preferably polyamide 4,10 is present in the rear layer of the backsheet. A polyolefin layer is preferably present in the core layer of the backsheet. It is however also possible that the polyamide is present in the core layer and polyolefin is present in the rear layer of the backsheet. The polyolefin is preferably chosen from the group consisting of polyethylene, polypropylene or ethylene-propylene copolymers. More preferably the polyolefin is polypropylene. The backsheet preferably comprises at least a further polymeric layer comprising a polymer selected from the group consisting of an optionally functionalized polyolefin such as a maleic anhydride functionalized polypropylene homo or copolymer. The present invention further relates to a photovoltaic module containing essentially, in order of position from the front-sun facing side to the back non-sun-facing side, a transparent pane, a front encapsulant layer, a solar cell layer comprised of one or more electrically interconnected solar cells, a back encapsulant layer and the back-sheet according to the present invention.

The present invention relates to a backsheet for photovoltaic modules comprising an aliphatic polyamide layer. The invention further relates to a photovoltaic module comprising the backsheet according to the present invention.

Photovoltaic modules are an important source of renewable energy. Solar cells or photovoltaic modules are used to generate electrical energy from sunlight. In particular, they include solar cells that release electrons when exposed to sunlight. These solar cells, which are usually semiconductor materials that may be fragile, are typically encapsulated in polymeric materials that protect them from physical shocks and scratches.

A photovoltaic module has a front surface protection sheet disposed on the side on which sunlight is incident, to protect the surface. This layer is for example a glass layer, which is a rigid outer layer that protects the PV cells and electronics from the environment while allowing light energy to pass through and be converted into electricity. The solar cell module also has a solar cell rear surface protection sheet called a backsheet, disposed on the opposite side to protect power generation cells.

The backsheet is in general a laminate that protects the cells from UV, moisture and weather while acting as an electrical insulator. The backsheet often comprises several polymeric layers to provide the above-mentioned properties and to minimize deterioration in the long-term performance of solar cell modules. Several polymeric layers have their own function in the backsheet. Normally a backsheet comprises a layer facing the cells, a core layer, a rear layer and at least a connecting or adhesive layer between the layer facing the cells and the core layer and/or between the core layer and the rear layer. A broad variety of polymers such as fluoro-polymers such as PVF, PVDF, acrylic resins, polyolefines, polyvinyl chloride, polyesters or polyamides can be used in a backsheet.

Fluor-containing polymers are widely used in backsheets because they typically display a very low water vapor transmission rate (WVTR) due to their apolar nature and their excellent hydrolytic and UV stability. The presence of Fluor-containing polymers is however a disadvantage because fluor-containing polymers are known as environmental unfriendly and they may cause toxic (HF) gasses when caught in a fire.

Backsheets comprising a polyamide layer are well known in the art. In for example EP-A-3109906 a back-sheet is disclosed comprising a rear layer, a connecting layer, a structural reinforcement layer and a reflective layer wherein the rear layer is a polyamide (PA 12) and the structural reinforcement layer is made of polypropylene. Backsheets comprising polyamide 12, polyamide 6 or polyamide 6,6 may however suffer from a too low melting point (PA12, Tm=180 C) and hydrolytic, or thermo-oxidative degradation. When these back-sheets are applied in photovoltaic modules this may cause accelerated ageing, leading to an increased power output decay upon lifetime. In case of too low melting point and/or poor thermo-oxidative stability, the backsheet used in the photovoltaic modules may also suffer from hot spot triggered localized melting and degradation. Hot spots are areas of elevated temperature affecting part of the solar panel. They are a result of a localized increase in cell resistance, decrease in efficiency, which results in lower power dissipation and an acceleration of the materials degradation in the affected area. Solar panels generate significant power and hot spots can occur when some of that power is dissipated in a localized area. Hot spots are rarely stable and will usually intensify until total failure of the panel performance in terms of electricity production and/or safety. Hot spots may occur e.g. due to partial cell shading and lead to a local dissipation in (part of) a single cell of the power generated in a string of the solar module. Then, local overheating may lead to destructive effects, such as glass cracking or degradation of the solar cells. The consequences of hot spots can range from dramatic fires to accelerated aging of the materials and, in most cases a more diffuse temperature increase leading to accelerated aging of the backsheet and encapsulation material.

There is a continuous demand for back-sheets with improved hydrolytic, UV or thermo-oxidative stability leading to better durability and improved hot spot resistance. It is moreover important that such a backsheet can be produced at lower production costs whereby the productivity and quality of the photovoltaic module is improved.

The object of the present invention is to provide a backsheet with increased thermo-oxidative stability reflected in dimensional, high temperature and improved hotspot stability. It is another object of the present invention to provide a backsheet with increased hydrolytic and UV stability.

This object has been achieved in that a backsheet is provided with a core and/or rear layer comprising an aliphatic polyamide containing monomer units of an aliphatic linear dicarboxylic acid with at least 8 carbon atoms.

It has surprisingly been found that the backsheet according to the present invention displays a superior thermal stability. Moreover, it has been found that due to the all-aliphatic nature of the polyamide, the intrinsic UV stability is good but can even be improved further via use of UV stabilizers. The backsheet comprising the aliphatic polyamides such as for example PA4,10 with UV and thermo-oxidative stabilizers surprisingly shows a combination of UV, hydrolytic and thermal-oxidative stability such that it passes damp-heat, thermal cycling and hot spot accelerated ageing tests. PV modules based on the backsheets according to the present invention will therefore be safe in use with high energy output for a longer period of time.

A multilayer film comprising polyamide 4,10 (PA 4,10) is known in the art. In WO11161115 discloses a multilayer film that comprises an aliphatic polyamide. These multilayer films provide good barrier properties, mechanical properties and good optical properties. The multilayer fims are disclosed as highly suitable for producing packaging of food. It is further disclosed that the multilayer film can be used as a cover sheet for solar cells or as a substrate for flexible circuit boards. Backsheets are not disclosed nor photovoltaic modules comprising the backsheet.

In the present invention the backsheet comprises a core and/or rear layer comprising an aliphatic polyamide containing monomer units of an aliphatic linear dicarboxylic acid with at least 8 carbon atoms chosen from the group consisting of 1,10-decanedioic acid, 1,11-undecandioic acid, 1,12-dodecanedioic acid, 1,13-tridecanedioic acid, 1,14-tetradecanedioic acid, 1,15-pentadecanedioic acid, 1,16-hexadecanedioic acid, 1,17-heptadecanedioic acid and 1,18-octadecanedioic acid. Preferably the aliphatic linear dicarboxylic acid is 1,10-decanedioic acid.

The aliphatic polyamide also contains at least a further monomer unit derived from a diamine alkane whereby the alkane comprises at least 4 carbon atoms. Preferably the diamine alkane is chosen from 1,4-diamine butane, 1,6-hexamethylene diamine or 1,5-pentamethylenediamine. Preferably the aliphatic polyamide is chosen from polyamide 4,10, polyamide 5,10 or polyamide 6,10.

The diamine alkane and the acid are preferably present in stoichiometric or at least about stoichiometric quantities. More preferred, the molar ratio between the diamine alkane and the acid is between 1:1 and 1:1.07 and most preferred the molar ratio is between 1:1 and 1.04:1.

The aliphatic polyamides may be prepared by making a solution of a salt of diamine alkane and aliphatic linear dicarboxylic acid in water, concentrating the solution of the salt at a temperature of between 100 and 180° C. and a pressure of between 0.8 and 6.0 bar to a water content of between 2 and 8 wt %. Producing a prepolymer containing monomer units of diamine alkane and aliphatic linear dicarboxylic acid from the salt at a temperature of between 180 and 210° C. and post-condensing of the prepolymer into the aliphatic polyamide. In WO2011138396 a more detailed description is given on the preparation of polyamide 4,10.

The aliphatic polyamide may be impact modified polyamide. The impact modifier may comprise a graft of a vinyl aromatic polymer on a rubbery substrate, a vinyl aromatic-conjugated diene-vinyl aromatic triblock polymer, a carboxylated vinyl aromatic-conjugated diene-vinyl aromatic triblock polymer, a carboxylated alpha-olefin polymer, a copolymer of an alpha-olefin compound and an unsaturated carboxylic compound, a graft of a rigid acrylic polymer on a rubbery substrate, a linear low density polyethylene, or mixtures thereof. Preferably the impact modifier comprises impact-modifying component, such as EP rubber, EPM rubber or EPDM rubber or SEBS. The impact modifier provides improved impact strength.

The backsheet preferably comprises a further polymeric layer comprising a polyolefin. Examples of polyolefins are polyethylene homo or copolymers, polypropylene homo or (block)-copolymers, cyclic olefin copolymers, polymethylpentene, a thermoplastic polyolefin's (TPO's) or blends thereof. The polyolefin may also be blended with polyethylene, ethylene-propylene copolymers, propylene-ethylene copolymers, polypropylene, plastomers, a thermoplastic polyolefin (TPO).

Examples of plastomers include but are not limited to copolymers of ethylene with at least one C3-C10 α-olefin comonomer. Plastomers are preferably produced using a metallocene catalyst, which term has a well-known meaning in the prior art. Plastomers are commercially available, such as plastomer products under tradename QUEO™, supplied by Borealis, or Engage™, supplied by ExxonMobil, Lucene supplied by LG, or Tafmer supplied by Mitsui.

A thermoplastic polyolefin (TPO) as described herein means for example PP/EPR reactor blends resins (such as Hifax CA 10, Hifax CA 12, Hifax CA 02, Hifax CA 60, supplied by Basell) or elastomeric PP resins (known under the trade name Versify 2300.01 or 2400.01 in mixture with e.g. random PP copolymers) or thermoplastic vulcanisates (known under the trade name Santoprene)

Preferably polypropylene is used as polyolefin. The polypropylene may in principle be of any customary commercial polypropylene type, such as isotactic or syndiotactic homo polypropylene, a random copolymer of propylene with ethylene and/or but-1-ene, a propylene-ethylene block copolymer.

The polyolefins may be prepared by any known process, for example by the Ziegler-Natta method or by means of metallocene catalysis. It is possible to combine the polyolefins with an impact-modifying component, such as EP rubber, EPM rubber or EPDM rubber or SEBS.

In one embodiment the backsheet rear layer comprises the aliphatic polyamide. Preferably the polyolefin layer is than present in the core of the backsheet. It has surprisingly been found that this backsheet provides a superior hot spot resistance. It seems that a more apolar or aliphatic nature of the polyamide such as PA 4,10 leads to superior dielectric properties at high Relative Humidity (i.e., better dielectric breakdown strength).

In a second embodiment the backsheet core layer comprises the aliphatic polyamide. Preferably the polyolefin layer is than present in the rear layer of the backsheet. Due to the more apolar nature of polyolefins the ingress of water can be reduced significantly. This, in combination with a higher acetic acid transmission rate in polyamides, significantly reduces hydrolysis of EVA encapsulants and any acetic acid formed upon hydrolysis can migrate out of the module leading to largely reduced corrosion of electrical contacts and hence superior power output over time.

The backsheet according to the present invention may comprise at least a further polymeric layer facing the cells comprising a polyolefin. Preferably the polyolefin is a functionalized polyolefin.

The functionalized polyolefin is for example an ethylene copolymer such as ethylene vinylacetate, ethylene-maleic anhydride copolymer or ethylene alkyl (meth)acrylate copolymer. Examples of suitable ethylene alkyl (meth)acrylate copolymer include, but are not limited to, ethylene-methyl acrylate copolymer, ethylene-ethyl acrylate copolymer, ethylene-propyl acrylate copolymer, ethylene-butyl acrylate copolymer, ethylene-acrylate-acrylic acid ternary copolymer, ethylene-acrylic acid copolymer, ethylene-methacrylic acid copolymer, ethylene-acrylic acid ionic polymer or maleic anhydride graft polyethylene. The functionalized polyolefin may be blended with polyethylene, ethylene-propylene copolymers, propylene-ethylene copolymers, polypropylene, plastomers, a thermoplastic polyolefin (TPO) or ethylene terpolymers functionalized with glycidyl methacrylate.

The polymeric layer facing the cells may in addition to the (functionalized) polyolefin also comprise a semi-crystalline polymer such as a semi-crystalline polyolefin, polyester or polyamide.

By the term “semi-crystallinity” it is understood that the polymer has a crystallinity typically ranging between 10 and 80%. Preferably the crystallinity of the polymer is greater than 30%. The assessment of a polymer's crystallinity can be most easily performed using differential scanning calorimetry (DSC) which measures the heat flow into or from a sample as it is either heated, cooled or under isothermally. The Pyris 6, DSC from PerkinElmer for example provides a means of measuring the percent crystallinity of thermoplastic materials. DSC measurement is well known in the art.

Examples of semi-crystalline polyolefins are for example polyethylene, polypropylene homo and copolymers, maleic anhydride grafted polypropylene and/or polybutylene, with polypropylene copolymers being the most preferred.

Examples of semi-crystalline polyamides are polyamide 6; polyamide 6,6; polyamide 4,6; polyamide 4,10, polyamide 6,10; polyamide 6,12; polyamide 6,14; polyamide 6,13; polyamide 6,15; polyamide 6,16; polyamide 11; polyamide 12; polyamide 10; polyamide 9,12; polyamide 9,13; polyamide 9,14; polyamide 9,15; polyamide 6,16; polyamide 10,10; polyamide 10,12; polyamide 10,13; polyamide 10,14; polyamide 12,10; polyamide 12,12; polyamide 12,13; polyamide 12,14; adipamide polyethylene terephthalate, polyethylene terephthalate azelaic acid amide, polyethylene sebacic acid amide, polyethylene terephthalate twelve diamide, adipic adipamide/terephthalic adipamide copolyamide, adipamide terephthalate/isophthalate copolymerized adipamide amide, m-xylene polyadipates amide, terephthalic acid adipamide/terephthalic acid methyl glutaramido, adipic adipamide/terephthalate adipamide/isophthalate copolyamides adipamide, polycaprolactam-terephthalate adipamide. polyamide 12 and any mixtures thereof. Preferred polyamides are selected with limited moisture uptake such as polyamide 11 or polyamide 12.

Examples of semi-crystalline polyesters include poly(trans-1,4-cyclohexylene alkane dicarboxylates such as poly(trans-1,4-cyclohexylene succinate) and poly(trans-1,4-cyclohexylene adipate), poly(cis or trans-1,4-cyclohexanedimethylene), alkanedicarboxylates such as poly(cis 1,4-cyclohexanedimethylene)oxalate and poly(cis 1,4-cyclohexanedimethylene)succinate, poly(alkylene terephthalates) such as polyethyleneterephthalate and polytetramethyleneterephthalate, poly(alkylene isophthalates such as polyethyleneisophthalate and polytetramethyleneisophthalate, poly(p-phenylene alkanedicarboxylates such as poly(p-phenylene glutarate) and poly(p-phenylene adipate), poly(p-xylene oxalate), poly(o-xylene oxalate), poly(p-phenylenedialkylene terephthalates) such as poly(p-phenylenedimethylene terephthalate) and poly(p-phenylene-di-1,4-butylene terephthalate, poly(alkylene-1,2-ethylenedioxy-4,4′-dibenzoates) such as poly(ethylene-1,2-ethylenedioxy-4,4′-dibenzoates), poly(tetramethylene-1,2-ethylenedioxy-4,4′-dibenzoate) and poly(hexamethylene-1,2-ethylenedioxy-4,4′-dibenzoate), poly(alkylene-4,4′-dibenzoates) such as poly(pentamethylene-4,4′-dibenzoate), poly(hexamethylene-4,4′-dibenzoate and poly(decamethylene-4,4′-dibenzoate), poly(alkylene-2,6-naphthalene dicarboxylates) such as poly(ethylene-2,6-naphthalene dicarboxylates), poly(trimethylene-2,6-naphthalene dicarboxylates) and poly(tetramethylene-2,6-naphthalene dicarboxylates), and poly(alkylene sulfonyl-4,4′-dibenzoates) such as poly(octamethylene sulfonyl-4,4′-dibenzoate) and poly-(decamethylene sulfonyl-4,4′-dibenzoate. Preferred polyesters are poly(alkylene terephthalates) such as polyethylene terephthalate (PET) or polybutylene terephthalate (PBT).

The backsheet according to the present invention may further comprise a connecting or adhesive layer, which may be arranged between the layer facing the cells and the core layer and/or between the core layer and the rear layer. The adhesive layer for example comprises a maleic anhydride grafted polyolefin such as maleic anhydride grafted polyethylene or maleic anhydride grafted polypropylene, an ethylene-acrylic acid copolymer or an ethylene-acrylic ester-maleic anhydride terpolymer. Preferably, the adhesive layer comprises maleic anhydride grafted polyolefine such as a maleic anhydride grafted polyethylene or a maleic anhydrate grafted polypropylene.

The polymeric layers may further comprise additives or inorganic fillers known the art. Examples of these inorganic fillers are calcium carbonate, titanium dioxide, barium sulfate, mica, talc, kaolin, ZnO, ZnS, glass microbeads and glass fibers. When such fillers are used, the polymeric layer comprises from 0.05-25 wt. % of filler based on the total weight of the polymers in the layer. White pigments such as TiO2, ZnO or ZnS may be added to increase backscattering of sunlight leading to increased efficiency of the solar module. Black pigments such as carbon black may also be added for esthetic reasons.

Example of the additives are selected from UV stabilizers thermal stabilizers, thermo-oxidative stabilizers and/or hydrolysis stabilizers. Specific examples of UV stabilizers are UV absorbers, Quenchers, and Hindered Amine Light Stabilizers. Specific examples of hydrolysis stabilizers are epoxide and carbodiimide containing compounds. Specific examples of thermo-oxidative stabilizers are copper-based stabilizers such as copper salts and complexes with or without a halogen-based salt, antioxidants such as sterically hindered phenols and aromatic amines, phosphites and thioethers. Preferably the aliphatic polyamide is stabilized using a Cu salt or complex in combination with a halogen salts. When such stabilizers are used, the polymeric layer comprises from 0.01-5 wt. %, preferably up to 4 wt %, more preferably up to 3 wt. % stabilizer based on the total weight of the polymer in the layer. The backsheet comprising the aliphatic polyamides stabilized with a copper containing compound, surprisingly shows a combination of UV, hydrolytic and thermal-oxidative stability such that it passes damp-heat, thermal cycling and hot spot accelerated ageing tests. Example of the additives are selected from UV stabilizers, UV absorbers, anti-oxidants, thermal stabilizers, thermo-oxidative stabilizers and/or hydrolysis stabilisers. Specific examples of thermo-oxidative stabilizers are Copper (Cu)/iodine salt, sterically hindered phenols or phosphites. Preferably the aliphatic polyamide is stabilized using Cu/iodine salt. When such stabilizers are used, the polymeric layer comprises from 0.05-5 wt. % more preferably up to 1 wt. % stabilizer based on the total weight of the polymer in the layer. The backsheet comprising the aliphatic polyamides stabilized with Copper (Cu)/iodine salt, surprisingly shows a combination of UV, hydrolytic and thermal-oxidative stability such that it passes damp-heat, thermal cycling and hot spot accelerated ageing tests.

The thickness of the back-sheet is preferably from 0.1 to 0.8 mm, more preferably from 0.1 to 0.5 mm.

The back-sheet may be prepared using a multi-layer fusion/or co-extrusion process. The process therefore comprises the steps of compounding the individual formulations of the core layer, the rear layer, the layer facing the cells and the adhesive layer including inorganic fillers and stabilizers followed by extrusion of the different layers and laminating them.

Also possible is that the back-sheet is obtained by melt co-extruding of the different layers in the back-sheet via the following steps: (1) preparing the polymer compositions of the different layers by separately mixing the components of the different layers, (2) melting of the different polymer compositions to obtain different melt streams, (3) combining the melt streams by co-extrusion in one extrusion die, (4) cooling the co-extruded layer.

The present invention further relates to a photovoltaic module comprising the back-sheet according to the present invention. A photovoltaic module (abbreviated PV module) comprises at least the following layers in order of position from the front sun-facing side to the back non-sun-facing side: (1) a transparent pane (representing the front sheet), (2) a front encapsulant layer, (3) a solar cell layer, (4) a back encapsulant layer, and (5) the back-sheet according to the present invention, representing the rear protective layer of the module.

The front sheet is typically a glass plate.

The front and back encapsulant used in solar cell modules are designed to encapsulate and protect the fragile solar cells. The “front side” corresponds to a side of the photovoltaic cell irradiated with light, i.e. the light-receiving side, whereas the term “backside” corresponds to the reverse side of the light-receiving side of the photovoltaic cells. Suitable encapsulants typically possess a combination of characteristics such as high impact resistance, high penetration resistance, good ultraviolet (UV) light resistance, good long term thermal stability, adequate adhesion strength to glass and/or other rigid polymeric sheets, high moisture resistance, and good long-term weather ability. Examples of encapsulants are ionomers, ethylene vinyl acetate (EVA), poly(vinyl acetal), polyvinylbutyral (PVB), thermoplastic polyurethane (TPU) or polyvinylchloride (PVC), metallocene-catalyzed linear low density polyethylenes, polyolefin block elastomers, poly(ethylene-co-methyl acrylate) and poly(ethylene-co-butyl acrylate), silicone elastomers or epoxy resins. EVA is the most commonly used encapsulant material. EVA sheets are usually inserted between the solar cells and the top surface (called front encapsulant) and between the solar cells and the rear surface (called a back encapsulant).

The photovoltaic module comprising the back-sheet according to the present invention surprisingly provides more thermal stability, hydrolytic and UV stability, and hot spot resistance which results in increased durability and a reduced power output decay during ageing tests and lifetime.

The photovoltaic module is typically manufactured by (a) providing an assembly comprising one or more polymeric layers as recited above and (b) laminating the assembly to form the solar cell module. The laminating step may be conducted by subjecting the assembly to heat and optionally vacuum or pressure.

The present invention will now be described in detail with reference to the following non-limiting examples which are by way of illustration.

### EXAMPLES

### Preparation Examples

The following preparation examples were obtained by mixing the specified weight % of each component, as shown in Table 1, and extruding at a rate of 20 Kg/h, with a screw speed of 250 rpm to produce pellets. Preparation Example 1 was extruded at 321° C. and 11 bar; Preparation Example 2 was extruded at 313° C. and 3 bar; and Preparation Example 3 was extruded at 316° C. and 4 bar. 100 kg of each sample was produced.

TABLE 1

| Preparation | Prep. Ex. 1 | Prep. Ex. 2 | Prep. Ex. 3 |
|---|---|---|---|
| Example Number | [wt. %] | [wt. %] | [wt. %] |
| Polyamide 4,10 | 68.25% | | |
| (MVR 26) | | | |
| Polyamide 4,10 | | 68.25% | |
| (MVR 52) | | | |
| Akulon ® F128 | | | 68.25 |
| (polyamide 6) | | | |
| Queo 8201 | 5.00 | 5.00 | 5.00 |
| Plastomer | 5.00 | 5.00 | 5.00 |
| Irganox 1098 | 0.50 | 0.50 | 0.50 |
| Tinivin 1577 | 1.00 | 1.00 | 1.00 |
| Chimassorb 2020 | 0.25 | 0.25 | 0.25 |
| TiO₂ R105 | 20.00 | 20.00 | 20.00 |
| Total | 100.0 | 100.0 | 100.0 |

Akulon® F238 is a polyamide 6 from DSM. Queo™ 8201 is an ethylene plastomer from Borealis. Irganox® 1098 is a discolouring stabilizer for polymers form BASF. Tinuvin® 1577 is a UVA light absorber from BASF. Chimasorb® 2020 is a light stabilizer from BASF.

MVR is the melt viscosity rate of the polyamide 4,10. MVR is measured at 270° C. and 5 Kg, reported in mL/10 min.

### Preparation of Material Stack

Material of a weathering layer (rear facing layer) of the Preparation Examples, a tie layer (adhesive layer), a structural layer (core layer) and a functional layer (layer facing cells) are respectively extruded and pelletized to obtain plastic pellets of each of the respective layers.

The weathering layer comprised granules of one material selected from Prep. Ex. 1, Prep. Ex. 2 and Prep. Ex. 3.

The tie layer comprised maleic anhydride grafted polypropylene and α-olefin block copolymer.

The core layer comprised copolymerised polypropylene.

The functional layer comprised polyethylene; ethylene copolymer; and copolymerized polypropylene.

For each example, the pellets were fed to one of multiple extruders, melt-extruded at a high temperature, passed through an adapter and a die, cooled by a cooling roller and shaped into a multi-layer film having a total thickness of 300 μm. Each example had, in order, the composition shown in Table 2.

TABLE 2

| | Weathering | Weathering layer | Tie layer | Structural layer | Tie layer | Functional layer |
|---|---|---|---|---|---|---|
| Example | layer | thickness | thickness | thickness | thickness | thickness |
| No. | material | [μm] | [μm] | [μm] | [μm] | [μm] |
| Ex. 1 | Prep. Ex. 1 | 20 | 25 | 200 | 25 | 30 |
| Ex. 2 | Prep. Ex. 1 | 40 | 25 | 180 | 25 | 30 |
| Ex. 3 | Prep. Ex. 2 | 20 | 25 | 200 | 25 | 30 |
| Ex. 4 | Prep. Ex. 2 | 40 | 25 | 180 | 25 | 30 |
| Comp. | Prep. Ex. 3 | 20 | 25 | 200 | 25 | 30 |
| Ex. A | | | | | | |
| Comp. | Prep. Ex. 3 | 40 | 25 | 180 | 25 | 30 |
| Ex. B | | | | | | |

### Shrinkage

Samples were cut from materials of the Examples. The samples were heated to 150° C. for 30 minutes. Dimensions were measured by hand before and after treatment and % change calculated. Results are given in Table 3.

TABLE 3

| | Weathering | Weathering | Shrinkage | Shrinkage |
|---|---|---|---|---|
| | layer | layer thickness | (machine | (transverse |
| Example No. | material | [μm] | direction) [%] | direction) [%] |
| Ex. 2 | Prep. Ex. 1 | 40 | 0.3 | 0.3 |
| Ex. 4 | Prep. Ex. 2 | 40 | 0.3 | 0.4 |
| Comp. Ex. B | Prep. Ex. 3 | 40 | 0.3 | 0.5 |

The results indicate that while shrinkage in the machine direction in all three examples is equivalent, shrinkage in the transverse direction is lower for the Examples 2 and 4 (PA4,10-containing samples) than for the Comparative Example B (PA6-containing sample. This indicates improved dimensional stability of a backsheet.

Yellowing Index after Damp Heat

The Examples were subjected to damp heat ageing in a \kitsch VC4200 climate chamber at a temperature of 85° C. and a relative humidity of 85% for 1000 hours. After this time, the samples were removed and colour was measured on a Minolta CM3700d spectrophotometer using D65 as illuminant, d/8 geometry, 10° viewing angle, specular included and UV included. These measurements were done using a white calibration tile as background. The change in yellowing index was calculated according to ASTM E313-96. Yellowing was measured directly on the weathering layer side of the multilayer sheet. Results are given in Table 4.

TABLE 4

| | Weathering layer | Weathering layer | Yellowing Index |
|---|---|---|---|
| Example | material | thickness [μm] | after 1000 hours |
| Ex. 3 | Prep. Ex. 2 | 20 | 8.1 |
| Comp | Prep. Ex. 3 | 20 | 9.7 |
| Ex. A | | | |
| Ex. 4 | Prep. Ex. 2 | 40 | 7.2 |
| Comp. | Prep. Ex. 3 | 40 | 8.6 |
| Ex. B | | | |

The results indicate that after long exposure to high temperature and humidity, a coextruded stack of Examples 3 and 4 (comprising PA 4,10) displays less yellowing than a coextruded stack of Comparative Examples A and B (comprising PA 6). This is an improvement in high temperature stability of a backsheet of the present invention.

### Breakdown Voltage

Samples were tested for breakdown DC voltage according to IEC TS62788-2. Results are given in Table 5.

TABLE 5

| | Weathering layer | Weathering layer | Breakdown voltage |
|---|---|---|---|
| Example No. | material | thickness [μm] | [kV] |
| Ex. 1 | Prep. Ex. 1 | 20 | 26.4 |
| Ex. 3 | Prep. Ex. 2 | 20 | 27.9 |
| Comp. Ex. A | Prep. Ex. 3 | 20 | 25.9 |

The results indicate that a backsheet of Examples 1 and 4 (comprising PA4,10) has a higher breakdown voltage than a backsheet of Comparative Example A (comprising PA6). This indicates increased electrical resistance of a backsheet of the present invention.

### Water Vapour Transmission Rate (WVTR)

A sample of polymer sheet of 210*297 mm (A4) size and specified thickness was produced by a standard film extrusion process. Akulon® F136E1 is a polyamide 6 and was obtained from DSM. Ecopaxx® Q150 is a polyamide 4,10 and was obtained from DSM.

Each sample was subjected to water vapour transmission rate analysis in a Mocon Aquatran water vapor permeation instrument according to DIN 53122 part 2. The temperature was 23° C. and relative humidity was 0/85%+/−3%. Results are given in Table 6.

TABLE 6

| | | | WVTR | WVTR |
|---|---|---|---|---|
| Example | | Thickness | [mg/m2 · | [mg · mm/ |
| No. | Material | [μm] | day] | m2 · day] |
| Ex. 5 | Ecopaxx ® Q150 | 65 | 19197 | 1248 |
| | (PA4,10) | | | |
| Comp. | Akulon ® F136E1 | 69.6 | 29291 | 2039 |
| Ex. C | (PA6) | | | |

The results show that Example 5 (PA4,10) has a lower water vapour transmission rate than Comparative Example C (PA6). This indicates that a backsheet comprising PA4,10 would have improved water barrier properties compared with one having a PA6 weathering layer.

### Hydrolytic Stability

A sample of unstabilized polymer sheet of polyamide (PA) thickness 1 mm was produced by injection molding into a tensile bar according to ISO 527-1 BA. Each sheet was subjected to damp and heat by boiling in tap water at 135° C. and 3.1 bar for a specified time. Samples were then removed, allowed to cool to room temperature and subjected to a tensile strength test, while still damp. The sample was subjected to extension along its major axis at 50 mm/min until break. Results are shown in Table 7.

TABLE 7

| | Tensile strength [MPa] | | |
|---|---|---|---|
| Time of | Comp. Ex. D | Comp Ex. E | Ex. 6 |
| treatment [h] | PA6 | PA6,6 | PA4,10 |
| 24 | 38.00 | 46.00 | 48.00 |
| 200 | 36.00 | 37.00 | 47.00 |
| 500 | — | — | 29.00 |
| 1000 | — | — | 8.00 |

At 500 hours and above, the samples of Comparative Example D (PA6) and Comparative Example E (PA6,6) had lost structural integrity such that they could not be tested for tensile strength. Example 6 (PA4,10) still provided adequate results after heating for 1000 hours.

The results show that a PA4,10 has a higher tensile strength after damp heat treatment than a PA6 or PA6,6. This indicates that a backsheet comprising a PA4,10 would have improved structural properties in damp and warm environmental conditions compared with one having PA6 or PA6,6. This is an indication of an improvement in dimensional stability of a backsheet according to the present invention.

1. Backsheet for photovoltaic modules comprising a core and/or rear layer comprising an aliphatic polyamide containing monomer units of an aliphatic linear dicarboxylic acid with at least 8 carbon atoms.

2. Backsheet according to claim 1 whereby the aliphatic linear dicarboxylic acid is chosen from the group of 1,10-decanedioic acid, 1,11-undecandioic acid, 1,12-dodecanedioic acid, 1,13-tridecanedioic acid, 1,14-tetradecanedioic acid, 1,15-pentadecanedioic acid, 1,16-hexadecanedioic acid, 1,17-heptadecanedioic acid and 1,18-octadecanedioic acid.

3. Backsheet according to claim 1 whereby the aliphatic linear dicarboxylic acid is 1,10-decanedioic acid.

4. Backsheet according to claim 1 whereby the aliphatic polyamide also contains at least a further monomer unit derived from a diamine alkane whereby the alkane comprises at least 4 carbon atoms.

5. Backsheet according to claim 4 whereby the diamine alkane is chosen from 1,4-diamine butane, 1,6-hexamethylene diamine or 1,5-pentamethylenediamine.

6. Backsheet according to claim 1 whereby the aliphatic polyamide is chosen from polyamide 4,10, polyamide 5,10 or polyamide 6,10.

7. Backsheet according to claim 1 whereby the aliphatic polyamide is impact modified polyamide.

8. Backsheet according to claim 1 whereby the backsheet comprises a further polymeric layer comprising a polyolefin.

9. Backsheet according to claim 1 whereby the aliphatic polyamide is present in the rear layer of the backsheet.

10. Backsheet according to claim 9 whereby the polyolefin layer is present in the core layer of the backsheet.

11. Backsheet according to claim 1 whereby the polyamide is present in the core layer of the backsheet.

12. Backsheet according to claim 11 whereby the polyolefin is present in the rear layer of the backsheet.

13. Backsheet according to claim 8 whereby the polyolefin is chosen from the group consisting of ethylene homo or copolymers, propylene homo or copolymers, ethylene-propylene copolymers, propylene-ethylene copolymers, ethylene-norbornene copolymers or polymethylpentene.

14. Backsheet according to claim 13 whereby the polyolefin is a polypropylene homopolymer, an ethylene-propylene copolymer, a propylene-ethylene copolymer or a mixture thereof.

15. Backsheet according to claim 1 whereby the backsheet comprises at least a further polymeric layer facing the cells comprising a functionalized polyolefin.

16. Backsheet according to claim 15 whereby the functionalized polyolefin is selected from the group consisting of ethylene vinylacetate, ethylene-maleic anhydride copolymer or ethylene alkyl (meth)acrylate copolymers.

17. Backsheet according to claim 1 further comprising at least a connecting or adhesive layer between the layer facing the cells and the core layer and/or the core layer and the rear layer.

18. Backsheet according to claim 17 whereby the adhesive layer comprises a polymer selected from the group consisting of maleic anhydride grafted polyethylene or maleic anhydrate grafted polypropylene.

19. Photovoltaic module comprising the backsheet according to claim 1.

20. Photovoltaic module according to claim 19 containing essentially, in order of position from the front-sun facing side to the back non-sun-facing side, a transparent pane, a front encapsulant, a solar cell layer comprised of one or more electrically interconnected solar cells, a back encapsulant and the back-sheet.
